(19) United States
(12) Patent Application Publication
(10) Pub. No.: US 2015/0194604 A1
(43) Pub. Date: Jul. 9, 2015

(54) VAPOR DEPOSITION APPARATUS, VAPOR DEPOSITION METHOD AND METHOD FOR MANUFACTURING ORGANIC LIGHT-EMITTING DISPLAY APPARATUS

(71) Applicant: Samsung Display Co., Ltd., Yongin-city (KR)

(72) Inventors: Choel-Min Jang, Yongin-City (KR); Sung-Hun Key, Yongin-City (KR); In-Kyo Kim, Yongin-City (KR); Suk-Won Jung, Yongin-City (KR); Myung-Soo Huh, Yongin-City (KR)

(73) Assignee: Samsung Display Co., Ltd., Yongin-city (KR)

(21) Appl. No.: 14/293,205

(22) Filed: Jun. 2, 2014

(30) Foreign Application Priority Data
Jan. 7, 2014 (KR) 10-2014-0002084

(51) Int. Cl. H01L 51/00; C23C 16/455; H01L 51/56; C23C 16/50

(52) U.S. Cl. CPC H01L 51/0002; C23C 16/50; C23C 16/45574; C23C 16/45523; H01L 51/56

(57) ABSTRACT

A vapor deposition apparatus for depositing a thin layer on a substrate, the vapor deposition apparatus includes a plurality of modules arranged to respectively face different regions of the substrate, each of the plurality of modules including a body unit, and a nozzle unit disposed on one of surfaces of the body unit facing the substrate, where the plurality of modules is configured to individually perform deposition processes on different regions of the substrate, respectively.

This application claims priority to Korean Patent Application No. 10-2014-0002084, filed on Jan. 7, 2014, and all the benefits accruing therefrom under 35 U.S.C. §119, the disclosure of which is incorporated herein in its entirety by reference.

### BACKGROUND

1. Field

One or more exemplary embodiments of the invention relate to a vapor deposition apparatus, a vapor deposition method and a method for manufacturing organic light-emitting display apparatus.

2. Description of the Related Art

Semiconductor devices, display apparatuses, and other electronic devices each include a plurality of thin layers. Such thin layers may be formed by using various methods including vapor deposition, for example.

The vapor deposition uses one or more gases as a raw material to form a thin layer. Such vapor deposition may include chemical vapor deposition (“CVD”), atomic layer deposition (“ALD”), and other various methods.

Among others, the ALD deposits, purges and pumps a raw material, then forms a single molecular layer or more layers on a substrate, then deposits, purges and pumps another raw material, and ultimately forms a desired single atomic layer or a desired number of atomic layers.

Since an organic light-emitting display (“OLED”) apparatus among display apparatuses has advantages in that its viewing angle is wide, its contrast is excellent and its response speed is fast, it receives attention as a next-generation display apparatus.

The OLED apparatus includes an intermediate layer including an organic emission layer between a first electrode and a second electrode that face each other, and further includes one or more thin layers. In this case, in order to form thin layers for the OLED apparatus, a vapor deposition process is also used.

Various attempts for enhancing the efficiency of the vapor deposition process for the formation of various thin layers and the characteristics of the thin layers are being made.

### SUMMARY

One or more exemplary embodiments of the invention include a vapor deposition apparatus, a vapor deposition method and a method for manufacturing organic light-emitting display (“OLED”) apparatus.

Additional exemplary embodiments will be set forth in part in the description which follows and, in part, will be apparent from the description, or may be learned by practice of the presented exemplary embodiments.

According to one or more exemplary embodiments of the invention, a vapor deposition apparatus for depositing a thin layer on a substrate includes a plurality of modules arranged to respectively face different regions of the substrate, where each of the plurality of modules includes a body unit, and a nozzle unit disposed on one of the surfaces of the body unit facing the substrate, where the plurality of modules are configured to individually perform deposition processes on different regions of the substrate, respectively.

In an exemplary embodiment, the nozzle units of the plurality of modules may be configured to independently supply a plurality of types of gases selectively to the substrate.

In an exemplary embodiment, the nozzle unit may be in a linear type to have a length corresponding to a width of the substrate taken along one direction.

In an exemplary embodiment, each of the plurality of modules may further include a plasma generating unit that is disposed on the one of the surfaces of the body unit facing the substrate and spaced apart from the nozzle unit.

In an exemplary embodiment, the vapor deposition apparatus may further include a plurality of matchers corresponding respectively to the plasma generating units of the plurality of modules, and a generator commonly connected to the plurality of matchers.

In an exemplary embodiment, the vapor deposition apparatus may further include a switch between the generator and the plurality of matchers and configured to transmit energy generated from the generator to a selected one of the plurality of matchers.

In an exemplary embodiment, the plurality of modules may have a size equal to or greater than an entire region of the substrate.

According to one or more exemplary embodiments of the invention, a vapor deposition method for providing a thin layer on a substrate includes providing a vapor deposition apparatus that includes a plurality of modules arranged to respectively face different regions of the substrate and each of the plurality of modules including a body unit and a nozzle unit disposed on one of surfaces of the body unit facing the substrate, arranging the substrate to face the plurality of modules of the vapor deposition apparatus, and sequentially supplying a plurality of raw material gases independently by the plurality of modules to the different regions of the substrate and providing a thin layer on the substrate.

In an exemplary embodiment, the vapor deposition method may further include selectively supplying a first raw material gas, a second raw material gas, and a purge gas to the substrate independently by the nozzle units of the plurality of modules.

In an exemplary embodiment, the vapor deposition method may further include supplying the first raw material gas or the second raw material gas by one of the nozzle units of the plurality of modules while supplying the purge gas to the substrate by another nozzle unit adjacent to the one of the nozzle unit.

In an exemplary embodiment, the nozzle units of the plurality of modules may be arranged in one direction, and the method may further include supplying the first raw material gas or the second raw material gas to the substrate by the plurality of modules in an arranged order.

In an exemplary embodiment, each of the plurality of modules may further include a plasma generating unit that is disposed on the one of the surfaces of the body unit facing the substrate and spaced apart from the nozzle unit, and the method may further include generating a plasma by the plasma generating unit while supplying at least one raw material gas in the providing the thin layer.

In an exemplary embodiment, the plasma generating units of the plurality of modules may independently generate plasmas.

In an exemplary embodiment, the providing the thin layer on the substrate may be performed while the substrate is fixed to the vapor deposition apparatus.

According to one or more exemplary embodiments of the invention, a method of manufacturing an OLED apparatus including one or more thin layers on a substrate includes providing a vapor deposition apparatus that includes a plurality of modules arranged to respectively face different regions of the substrate and each of the plurality of modules including a body unit and a nozzle unit disposed on one of surfaces of the body unit facing the substrate, arranging the substrate to face the plurality of modules of the vapor deposition apparatus, and sequentially supplying a plurality of raw material gases independently by the plurality of modules to the different regions of the substrate and providing a thin layer on the substrate.

In an exemplary embodiment, the providing the thin layer on the substrate may include selectively supplying a first raw material gas, a second raw material gas, and a purge gas to the substrate independently by the nozzle units of the plurality of modules.

In an exemplary embodiment, the method may further include supplying the first raw material gas or the second raw material gas by one of the nozzle units of the plurality of modules while supplying the purge gas to the substrate by another nozzle unit adjacent to the one of the nozzle unit.

In an exemplary embodiment, each of the plurality of modules may further include a plasma generating unit that is disposed on the one of the surfaces of the body unit facing the substrate and spaced apart from the nozzle unit, and the sequentially supplying the plurality of raw material gases may further include generating a plasma by the plasma generating unit while supplying at least one raw material gas.

In an exemplary embodiment, the OLED apparatus may include an organic light-emitting device that includes a first electrode, a second electrode, and an intermediate layer that is arranged between the first electrode and the second electrode and includes an organic emission layer, and the providing the thin layer on the substrate may include providing an encapsulating layer that encapsulates the organic light-emitting device.

In an exemplary embodiment, the providing the thin layer on the substrate may include providing one or more insulating layers or conductive layers that are included in the OLED apparatus.

### BRIEF DESCRIPTION OF THE DRAWINGS

These and/or other exemplary embodiments will become apparent and more readily appreciated from the following description of the exemplary embodiments, taken in conjunction with the accompanying drawings, in which:

FIG. 1 is a schematic perspective view of an exemplary embodiment of a vapor deposition apparatus according to the invention;

FIG. 2 is a cross-sectional view taken along line II-II of FIG. 1;

FIG. 3 is a schematic diagram of a valve that may be selectively included in the vapor deposition device of FIG. 1;

FIGS. 4A to 4F are sequential views of an exemplary embodiment of a vapor deposition method according to the invention;

FIG. 5 is a cross-sectional view of an organic light-emitting display (“OLED”) apparatus provided by using the method shown in FIGS. 4A to 4F; and

FIG. 6 is an enlarged view of a circled part F of FIG. 5.

### DETAILED DESCRIPTION

Since the invention may make various modifications and have several exemplary embodiments, particular exemplary embodiments will be illustrated in the drawings and described in the detailed description in detail. The effects and features of the invention, and implementation methods thereof will be clarified through following exemplary embodiments described with reference to the accompanying drawings. The invention may, however, be embodied in different forms and should not be construed as limited to the exemplary embodiments set forth herein.

Exemplary embodiments of the invention are described below in detail with reference to the accompanying drawings and when referring to the drawings, the same or similar components are denoted by the same reference numerals and are not repetitively described.

In the following exemplary embodiments, the terms a first, a second, etc. are not used as limited meanings but used for the purpose of distinguishing one component from another component.

In the following exemplary embodiments, the terms of a singular form may include plural forms unless referred to the contrary.

The meaning of “include”, “has”, “including”, or “having” specifies a characteristic or component described herein but does not exclude one or more characteristics or components.

When a part of a layer, an area, or a component is referred to as being “on” another part, it can be directly on the other part or intervening layers, areas, or components may also be present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

In the drawings, the sizes of components may be exaggerated or reduced for the convenience of description. In an exemplary embodiment, since the size and thickness of each component represented in the drawings is represented for the convenience of description, the invention is not necessarily limited to those shown.

In the following exemplary embodiments, x-axis, y-axis and z-axis may not be limited to three axes on a rectangular coordinate system but may be construed as a wide meaning including them. In an exemplary embodiment, x-axis, y-axis and z-axis may refer to directions orthogonal to one another but may also refer to other directions not orthogonal to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

When some exemplary embodiments may be implemented by using other methods, the order of specific processes may be different from that described. In an exemplary embodiment, two processes that are successively described may be performed substantially simultaneously or in an order opposite to that described.

Expressions such as “at least one of,” when preceding a list of elements, modify the entire list of elements and do not modify the individual elements of the list.

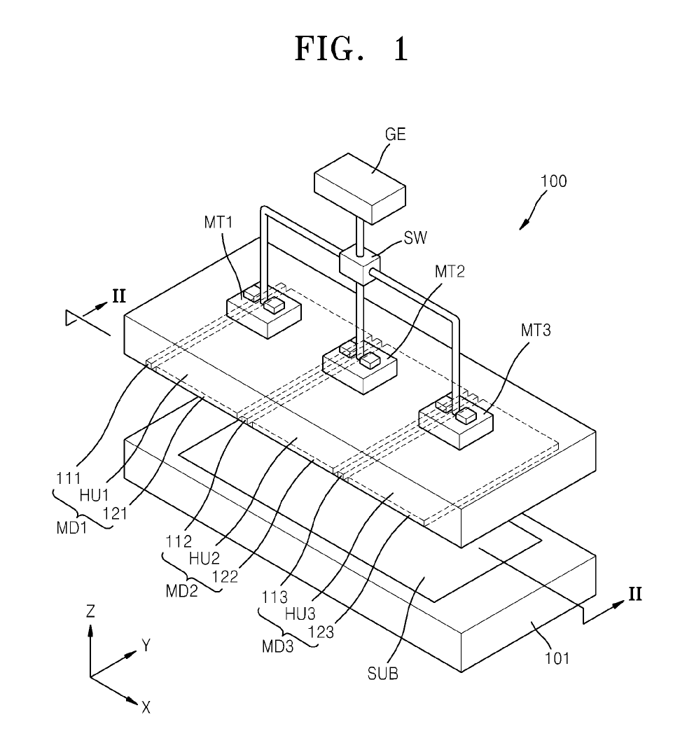

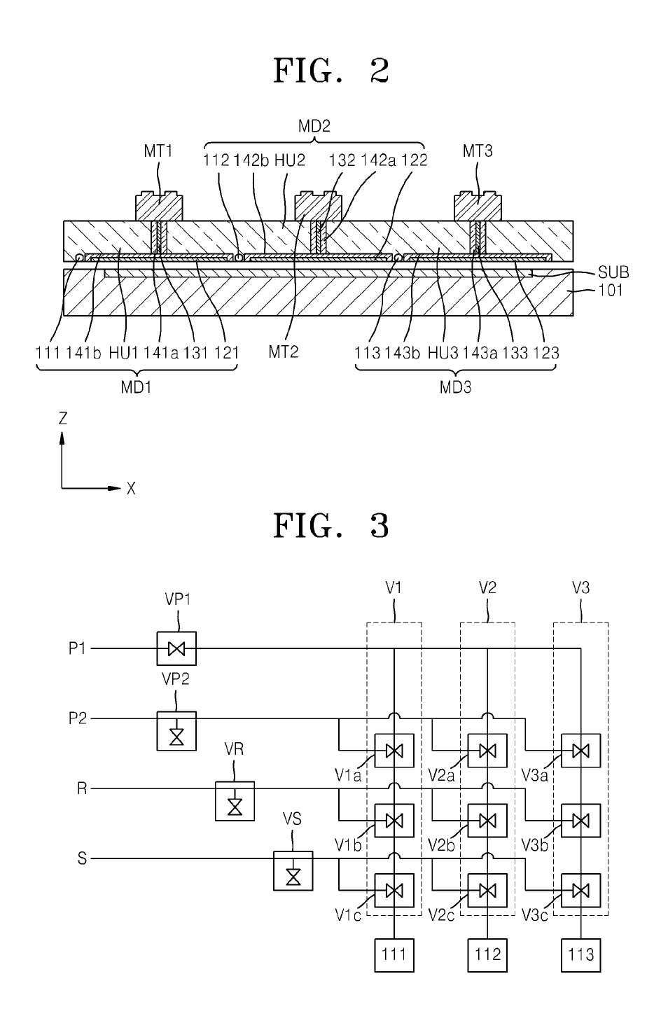

FIG. 1 is a schematic perspective view of a vapor deposition apparatus according to an exemplary embodiment of the invention, and FIG. 2 is a cross-sectional view taken along line II-II of FIG. 1.

Referring to FIGS. 1 and 2, a vapor deposition apparatus 100 according to the exemplary embodiment includes a plurality of modules MD1 to MD3 including a first module MD1, a second module MD2 and a third module MD3.

Moreover, the first module MD1, the second module MD2, and the third module MD3 respectively includes a first nozzle unit 111, a second nozzle unit 112, and a third nozzle 113 supplying one or more gases to a substrate SUB, and respectively includes a first plasma generating unit 121, a second plasma generating unit 122, and a third plasma generating unit 123.

The vapor deposition apparatus 100 performs a vapor deposition process on the substrate SUB to dispose one or more thin layers on the substrate SUB.

The plurality of modules MD1 to MD3 is arranged to face different regions of the substrate SUB so that the modules MD1 to MD3 perform a vapor process on the substrate SUB.

Each member is described in detail below.

The substrate SUB may be arranged on a stage 101 for stable arrangement when performing the vapor process. That is, the stage 101 stably fixes the substrate SUB while the vapor deposition process is performed. In an exemplary embodiment, the stage 101 may also include a clamp (not shown) and thus efficiently fix the substrate SUB to the stage 101 through the clamp. Moreover, as shown in FIG. 2, a groove may be defined in the stage 101 and the substrate SUB may be arranged in such a groove. Thus, the substrate SUB is stably arranged on the stage 101 to prevent the substrate SUB from becoming dislocated or shaking while the vapor deposition process is performed. However, the invention is not limited thereto, and the groove may not be defined in the stage 101.

Moreover, in an alternative exemplary embodiment, an adsorbing unit (not shown) may be disposed on the stage 101 to effectively arrange the substrate SUB on the stage 101.

The first module MD1, the second module MD2 and the third module MD3 are arranged to face the substrate SUB. That is, the first module MD1 is arranged to face the left region of the substrate SUB, the second module MD2 is arranged to face the intermediate region of the substrate SUB, and the third module MD3 is arranged to face the right region of the substrate SUB.

In this case, by enabling the first module MD1, the second module MD2, and the third module MD3 to face the entire substrate SUB, each of all regions of the top of the substrate SUB may face any one of the first module MD1, the second module MD2 and the third module MD3. Thus, by performing the vapor process on all the regions of the substrate SUB, it is possible to provide a deposition layer having a uniform characteristic.

The first module MD1, the second module MD2 and the third module MD3 will be described below in detail. Firstly, the first module MD1 is described.

The first module MD1 includes a first body unit HU1, a first nozzle unit 111, and a first plasma generating unit 121.

The first body unit HU1 functions as a housing that maintains the general shape of the first module MD1 and protects the module MD1.

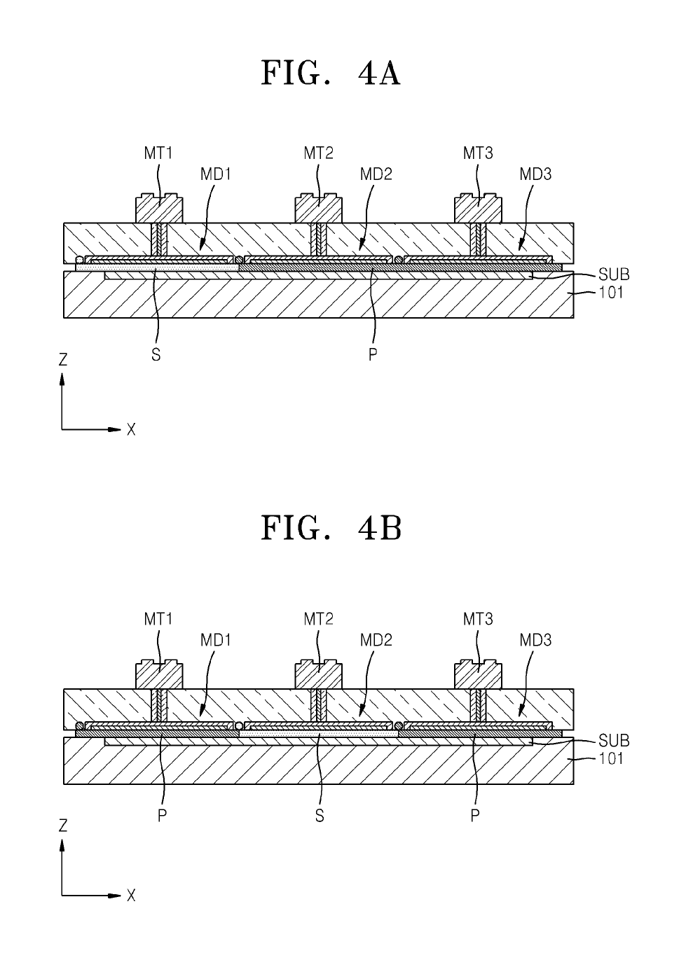

The first nozzle unit 111 is disposed on one of the surfaces of the first body unit HU1 that faces the stage 101 on which the substrate SUB is arranged. In an exemplary embodiment, the first nozzle unit 111 selectively supplies two or more kinds of gases to the substrate SUB. In an exemplary embodiment, the first nozzle unit 111 selectively supplies one or more raw materials and a purge gas to the substrate SUB. That is, it is possible to supply a first raw material gas, a second raw material gas, and a purge gas to the substrate SUB, for which the first nozzle unit 111 is connected to a plurality of gas supply sources and controls the flow of a gas through one or more valves. Related descriptions are provided below with reference to FIG. 3.

In an exemplary embodiment, the first nozzle unit 111 may have various shapes such as a line shape, for example. That is, the first nozzle unit 111 may have a shape extended to have a length corresponding to a width of at least one direction of the substrate SUB. In the illustrated exemplary embodiment, the length of the first nozzle unit 111 and the width of the substrate SUB are taken along Y-axis, for example.

The first nozzle unit 121 is disposed on one of the surfaces of the first body unit HU1 that faces the stage 101 on which the substrate SUB is arranged. The first plasma generating unit 121 is arranged to be spaced apart from the first nozzle unit 111. Moreover, the first plasma generating unit 121 is arranged to selectively generate a plasma when performing the vapor process. To this end, in an exemplary embodiment, the first plasma generating unit 121 may have an electrode shape. In an exemplary embodiment, the first plasma generating unit 121 may be a plate-shaped electrode, for example.

The generation of a plasma from the first plasma generating unit 121 may be implemented through various methods. As an exemplary embodiment, as shown in FIGS. 1 and 2, the plasma may be generated by using a generator GE, a first matcher MT1 and a first conductor unit 131. That is, the generator GE is connected to the first matcher MT1, which is electrically connected to the first plasma generating unit 121 through the first conductor unit 131. Moreover, in an alternative exemplary embodiment, a switch SW may be arranged between the first matcher MT1 and the generator GE. The generator GE may be in various types such as a radio frequency (“RF”) generator.

A first insulating unit 141a and a first insulating unit 141b are further provided between the first conductor unit 131 and the first body unit HU1 and between the first plasma generating unit 121 and the first body unit HU1 for electrical insulation. That is, the first insulating unit 141a is provided around sides of the first conductor unit 131. Moreover, the first insulating unit 141b is provided around sides and a top of the first conductor unit 121.

The second module MD2 includes a second body unit HU2, a second nozzle unit 112, and a second plasma generating unit 122.

The second body unit HU2 functions as a housing that maintains the general shape of the second module MD2 and protects the module MD2.

The second nozzle unit 112 is disposed on one of the surfaces of the second body unit HU2 that faces the stage 101 on which the substrate SUB is arranged. In an exemplary embodiment, the second nozzle unit 112 selectively supplies two or more kinds of gases to the substrate SUB. In an exemplary embodiment, the second nozzle unit 112 selectively supplies one or more raw materials and a purge gas to the substrate SUB. That is, it is possible to supply a first raw material gas, a second raw material gas, and a purge gas to the substrate SUB, for which the second nozzle unit 112 is connected to a plurality of gas supply sources and controls the flow of a gas through one or more valves. Related descriptions are provided below with reference to FIG. 3.

In an exemplary embodiment, the second nozzle unit 112 may have various shapes such as a line shape. That is, the second nozzle unit 112 may have a shape extended to have a length corresponding to the width of at least one direction of the substrate SUB. In the illustrated exemplary embodiment, the length of the second nozzle unit 112 and the width of the substrate SUB are taken along Y-axis, for example.

The second nozzle unit 112 is arranged to be spaced apart from the first plasma generating unit 121. In the illustrated exemplary embodiment, the second nozzle unit 112 is arranged between the first plasma generating unit 121 and the second plasma generating unit 122 in X-axis, for example.

The second plasma generating unit 122 is disposed on one of the surfaces of the second body unit HU2 that faces the stage 101 on which the substrate SUB is arranged. The second plasma generating unit 122 is arranged to be spaced apart from the second nozzle unit 112. Moreover, the second plasma generating unit 122 is arranged to selectively generate the plasma when performing the vapor process. To this end, in an exemplary embodiment, the second plasma generating unit 122 may have an electrode shape. In an exemplary embodiment, the second plasma generating unit 122 may be a plate-shaped electrode, for example.

The generation of the plasma from the second plasma generating unit 122 may be implemented through various methods. As an exemplary embodiment, as shown in FIGS. 1 and 2, the plasma may be generated by using the generator GE, a second matcher MT2 and a second conductor unit 132. That is, the generator GE is connected to the second matcher MT2, which is electrically connected to the second plasma generating unit 122 through the second conductor unit 132. Moreover, in an alternative exemplary embodiment, the switch SW may be arranged between the second matcher MT2 and the generator GE in Z-axis, for example.

A second insulating unit 142a and a second insulating unit 142b are further provided between the second conductor unit 132 and the second body unit HU2 and between the second plasma generating unit 122 and the second body unit HU2 for electrical insulation. That is, the second insulating unit 142a is provided around sides of the second conductor unit 132. Moreover, the second insulating unit 142b is provided around sides and a top of the second conductor unit 122.

The third module MD3 includes a third body unit HU3, a third nozzle unit 113, and a third plasma generating unit 123.

The third body unit HU3 functions as a housing that maintains the general shape of the third module MD3 and protects the module MD3.

The third nozzle unit 113 is disposed on one of the surfaces of the third body unit HU3 that faces the stage 101 on which the substrate SUB is arranged. In an exemplary embodiment, the third nozzle unit 113 selectively supplies two or more kinds of gases to the substrate SUB. In an exemplary embodiment, the third nozzle unit 113 selectively supplies one or more raw materials and a purge gas to the substrate SUB. That is, it is possible to supply a first raw material gas, a second raw material gas, and a purge gas to the substrate SUB, for which the third nozzle unit 113 is connected to a plurality of gas supply sources and controls the flow of a gas through one or more valves. Related descriptions are provided below with reference to FIG. 3.

In an exemplary embodiment, the third nozzle unit 113 may have various shapes such as a line shape. That is, the third nozzle unit 113 may have a shape extended to have a length corresponding to the width of at least one direction of the substrate SUB.

The third nozzle unit 113 is arranged to be spaced apart from the second plasma generating unit 122. In the illustrated exemplary embodiment, the third nozzle unit 113 is arranged between the second plasma generating unit 122 and the third plasma generating unit 123 in X axis, for example.

The third plasma generating unit 123 is disposed on one of the surfaces of the third body unit HU3 that faces the stage 101 on which the substrate SUB is arranged. The third plasma generating unit 123 is arranged to be spaced apart from the third nozzle unit 113. Moreover, the third plasma generating unit 123 is arranged to selectively generate a plasma when performing the vapor process. To this end, in an exemplary embodiment, the third plasma generating unit 123 may have an electrode shape. In an exemplary embodiment, the third plasma generating unit 123 may be a plate-shaped electrode, for example.

The generation of the plasma from the third plasma generating unit 123 may be implemented through various methods. As an exemplary embodiment, as shown in FIGS. 1 and 2, the plasma may be generated by using the generator GE, a third matcher MT3 and a third conductor unit 133. That is, the generator GE is connected to the third matcher MT3, which is electrically connected to the third plasma generating unit 123 through the third conductor unit 133. Moreover, in an alternative exemplary embodiment, the switch SW may be arranged between the third matcher MT3 and the generator GE in Z-axis, for example.

A third insulating unit 143a and a third insulating unit 143b are further provided between the third conductor unit 133 and the third body unit HU3 and between the third plasma generating unit 123 and the third body unit HU3 for electrical insulation. That is, the third insulating unit 143a is provided around sides of the third conductor unit 133. Moreover, the third insulating unit 143b is provided around sides and a top of the third plasma generating unit 123.

In an exemplary embodiment, the first body unit HU1, the second body unit HU2, and the third body unit HU3 of the first module MD1, the second module MD2, and the third module MD3, respectively, may be individually provided. However, in an alternative exemplary embodiment, as shown in FIGS. 1 and 2, since the first body unit HU1, the second body unit HU2, and the third body unit HU3 are integrally provided, it is possible to increase the general durability of the vapor deposition apparatus 100, and convenience in manufacturing and handling.

Moreover, since the illustrated exemplary embodiment includes three matchers MT1 to MT3 corresponding respectively to modules of one generator GE, the size of the vapor deposition apparatus 100 and power consumption decrease.

FIG. 3 is a schematic diagram of a valve that may be selectively included in the vapor deposition device of FIG. 1.

Referring to FIG. 3, a vapor deposition apparatus 100 according to the exemplary embodiment includes a plurality of gas supply sources P1, P2, S, and R.

In an exemplary embodiment, a first purge gas supply source P1, a second purge gas supply source P2, a first raw material gas supply source S and a second raw material gas supply source R are included. The second purge gas supply source P2 may be omitted due to a selective structure.

The first purge gas supply source P1 may be connected to all of the first nozzle unit 111, the second nozzle unit 112, and the third nozzle unit 113. The second purge gas supply source P2 may be connected to all of the first nozzle unit 111, the second nozzle unit 112, and the third nozzle unit 113. The first raw material gas supply source S may be connected to all of the first nozzle unit 111, the second nozzle unit 112, and the third nozzle unit 113. The second raw material gas supply source R may be connected to all of the first nozzle unit 111, the second nozzle unit 112, and the third nozzle unit 113.

The vapor deposition apparatus 100 includes valves that may control all supply from the first purge gas supply source P1, the second purge gas supply source P2, the first raw material gas supply source S and the second raw material gas supply source R to the first nozzle unit 111, the second nozzle unit 112 and the third nozzle unit 113.

In an exemplary embodiment, a first purge valve VP1 is arranged to control entire gas supply from the first purge gas supply source P1 to the first nozzle unit 111, the second nozzle unit 112, and the third nozzle unit 113.

A second purge valve VP2 is arranged to control all supply from the second purge gas supply source P2 to the first nozzle unit 111, the second nozzle unit 112, and the third nozzle unit 113.

A first raw material valve VS is arranged to control all supply from the first raw material gas supply source S to the first nozzle unit 111, the second nozzle unit 112, and the third nozzle unit 113.

A second raw material valve VR is arranged to control all supply from the second raw material gas supply source R to the first nozzle unit 111, the second nozzle unit 112, and the third nozzle unit 113.

The vapor deposition apparatus 100 includes a first valve unit V1 that may individually control gas supply from the first purge gas supply source P1, the second purge gas supply source P2, the first raw material gas supply source S and the second raw material gas supply source R to the first nozzle unit 111. The first valve unit V1 includes a first valve V1a, a first valve V1b, and a first valve V1c.

The first valve V1a controls supply from the second purge gas supply source P2 to the first nozzle unit 111. The first valve V1b controls supply from the second raw material gas supply source R to the first nozzle unit 111. The first valve V1c controls supply from the first raw material gas supply source S to the first nozzle unit 111.

The vapor deposition apparatus 100 includes a second valve unit V2 that may individually control supply from the first purge gas supply source P1, the second purge gas supply source P2, the first raw material gas supply source S and the second raw material gas supply source R to the second nozzle unit 112. The second valve unit V2 includes a second valve V2a, a second valve V2b, and a second valve V2c.

The second valve V2a controls supply from the second purge gas supply source P2 to the second nozzle unit 112. The second valve V2b controls supply from the second raw material gas supply source R to the second nozzle unit 112. The second valve V2c controls supply from the first raw material gas supply source S to the second nozzle unit 112.

The vapor deposition apparatus 100 includes a third valve unit V3 that may individually control supply from the first purge gas supply source P1, the second purge gas supply source P2, the first raw material gas supply source S and the second raw material gas supply source R to the third nozzle unit 113. The third valve unit V3 includes a third valve V3a, a third valve V3b, and a third valve V3c.

The third valve V3a controls supply from the second purge gas supply source P2 to the third nozzle unit 113. The third valve V3b controls supply from the second raw material gas supply source R to the third nozzle unit 113. The third valve V3c controls supply from the first raw material gas supply source S to the third nozzle unit 113.

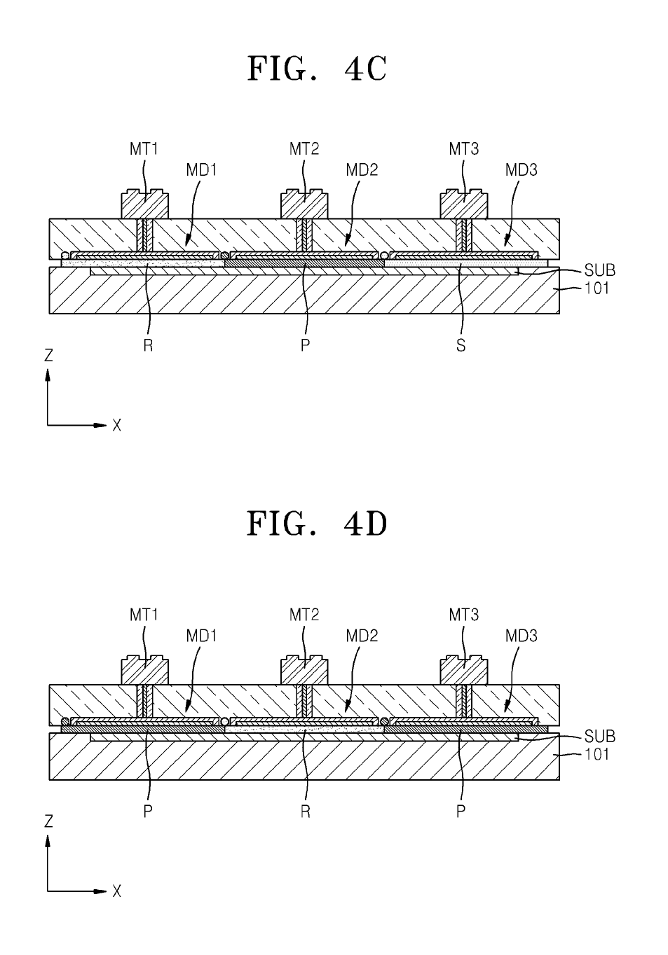

FIGS. 4A to 4F are sequential views of a vapor deposition method according to an exemplary embodiment of the invention. In an exemplary embodiment, FIGS. 4A to 4F sequentially show performing the vapor deposition process by using the vapor deposition apparatus 100 of FIGS. 1 to 3. The reference numerals of members of the first module MD1, the second module MD2 and the third module MD3 may be omitted in FIGS. 4A to 4F for the simplification of the drawings. The reference numerals of the members are the same as those of FIG. 2.

Referring first to FIGS. 3 and 4A, a first raw material S is supplied from the first module MD1 to the substrate, and a purge gas P is supplied from the second module MD2 and the third module MD3 to the substrate SUB. In an exemplary embodiment, the first raw material gas S is supplied from the first nozzle unit 111 of the first module MD1 to the substrate SUB. The purge gas P is supplied from the second nozzle unit 112 of the second module MD2 and the third nozzle unit 113 of the third module MD3 to the substrate SUB.

In this case, the first raw material valve VS and the first valve V1c among valves shown in FIG. 3 are open to supply the first raw material gas S from the first nozzle unit 111 to the substrate SUB.

The purge gas P may include various materials. In an exemplary embodiment, the purge gas P may include an inert gas, such as argon or nitrogen. By using the purge gas P, impurities are removed from the top of the substrate SUB and the cleanliness of a space in which the vapor deposition process is performed is maintained. In an alternative exemplary embodiment, before supplying the first raw material gas S from the first nozzle unit 111 of the first module MD1 to the substrate SUB, the purge gas P is first supplied and then the process of supplying the first raw material gas S may be performed.

The first raw material gas S may include various materials. In an exemplary embodiment, the first raw material gas S may include an aluminum (Al) including gas such as a trimethyl aluminum (“TMA”) gas. In this case, when the first raw material gas S is supplied to the substrate SUB, an adsorbing layer including aluminum (Al) is disposed on a surface of the substrate SUB including a region facing the first module MD1. In an exemplary embodiment, a chemical adsorbing layer and a physical adsorbing layer are disposed on a surface of the substrate SUB corresponding to the first module MD1.

Then, referring to FIGS. 3 and 4B, the first raw material S is supplied from the second module MD2 adjacent to the first module MD1 to the substrate SUB, and the purge gas P is supplied from the first module MD1 and the third module MD3 to the substrate SUB. In an exemplary embodiment, the first raw material gas S is supplied from the second nozzle unit 112 of the second module MD2 to the substrate SUB. The purge gas P is supplied from the first nozzle unit 111 of the first module MD1 and the third nozzle unit 113 of the third module MD3 to the substrate SUB.

In this case, the first raw material valve VS and the second valve V2c among valves shown in FIG. 3 are open to supply the first raw material gas S from the second nozzle unit 112 to the substrate SUB.

When the first raw material gas S is supplied to the substrate SUB, an adsorbing layer including aluminum (Al) is disposed on a surface of the substrate SUB including a region facing the second module MD2. In an exemplary embodiment, a chemical adsorbing layer and a physical adsorbing layer are disposed on a surface of the substrate SUB corresponding to the second module MD2.

In this case, since the purge gas P is supplied from the first nozzle unit 111 of the first module MD1 to the substrate SUB, the physical adsorbing layer having weak intermolecular bond among the adsorbing layers disposed on a region of the surface of the substrate SUB facing the first module MD1 by using the first raw material gas S is separated and exhausted from the substrate SUB by the purge gas P.

Then, referring to FIGS. 3 and 4C, the first raw material S is supplied from the third module MD3 adjacent to the second module MD2 to the substrate, and the purge gas P is supplied from the second module MD2 to the substrate SUB. In an exemplary embodiment, the first raw material gas S is supplied from the third nozzle unit 113 of the third module MD3 to the substrate SUB. The purge gas P is supplied from the second nozzle unit 112 of the second module MD2 to the substrate SUB. In this case, the first raw material valve VS and the third valve V3c among valves shown in FIG. 3 are open to supply the first raw material gas S from the third nozzle unit 113 to the substrate SUB.

When the first raw material gas S is supplied to the substrate SUB, an adsorbing layer including aluminum (Al) is disposed on a surface of the substrate SUB including a region facing the third module MD3. In an exemplary embodiment, a chemical adsorbing layer and a physical adsorbing layer are disposed on a surface of the substrate SUB facing the third module MD3.

In this case, since the purge gas P is supplied from the second nozzle unit 112 of the second module MD2 to the substrate SUB, the physical adsorbing layer having weak intermolecular bond among the adsorbing layers disposed on a region of the surface of the substrate SUB facing the first module MD2 by using the first raw material gas S is separated and exhausted from the substrate SUB by the purge gas P.

The second raw material gas R is supplied from the first module MD1 to the substrate SUB. In an exemplary embodiment, the second raw material gas R is supplied from the first nozzle unit 111 of the first module MD1 to the substrate SUB. In this case, the second raw material valve VR and the first valve V1b among valves shown in FIG. 3 are open to supply the second raw material gas R from the first nozzle unit 111 to the substrate SUB.

The second raw material gas R may include various materials. In an exemplary embodiment, the second raw material gas R may be an oxygen (O) containing gas such as H2O, O2 or N2O.

When the second raw material gas R is supplied to the substrate SUB, the gas reacts with the chemical adsorbing layer including the first raw material gas S already adsorbed on one of the regions of the substrate SUB facing the first module MD1 or substitutes a portion of the chemical adsorbing layer, and a desired deposition layer such as a AlxOy layer is ultimately provided. In this case, an extra second raw material gas R provides a physical adsorbing layer and then remains or is exhausted. In this case, the remaining second raw material gas R is exhausted.

In an alternative exemplary embodiment, when the second raw material gas R is supplied to the substrate SUB, the plasma is generated through the first plasma generating unit 121 of the first module MD1. In an exemplary embodiment, energy is selectively supplied from the generator GE (refers to FIG. 1) only to the first matcher MT1 through the switch SW, proper power is transmitted from the first matcher MT1 to the first plasma generating unit 121 through the first conductor unit 131, and the plasma is generated from the first plasma generating unit 121. The generated plasma may convert the second raw material gas R into a radical type, which may effectively react with a layer including the first raw material gas S.

Then, referring to FIGS. 3 and 4D, the second raw material R is supplied from the second module MD2 adjacent to the first module MD1 to the substrate, and the purge gas P is supplied from the first module MD1 and the third module MD3 to the substrate SUB. In an exemplary embodiment, the purge gas P is supplied from the first nozzle unit 111 of the first module MD1 and the third nozzle unit 113 of the third module MD3 to the substrate SUB.

In this case, the second raw material valve VR and the second valve V2b among valves shown in FIG. 3 are open to supply the second raw material gas R from the second nozzle unit 112 to the substrate SUB.

In this case, since the purge gas P is supplied from the third nozzle unit 113 of the third module MD3 to the substrate SUB, the physical adsorbing layer having weak intermolecular bond among the adsorbing layers disposed on a region of the surface of the substrate SUB facing the third module MD3 by using the first raw material gas S is separated and exhausted from the substrate SUB by the purge gas P.

The purge gas P is supplied from the first module MD1 to the substrate, removes extra layers and impurities remaining on the surface of the AlxOy layer disposed on the top of the substrate SUB, and provides a deposition layer including AlxOy on a region of the surface of the substrate SUB facing the first module MD1, so the deposition layer formation of one cycle on a region of the surface of the substrate SUB facing the first module MD1 is completed.

When the second raw material gas R is supplied to the substrate SUB, the gas reacts with the chemical adsorbing layer including the first raw material gas S already adsorbed on one of the regions of the substrate SUB facing the second module MD2 or substitutes a portion of the chemical adsorbing layer, and a desired deposition layer such as a AlxOy layer is ultimately provided. In this case, an extra second raw material gas R provides a physical adsorbing layer, and remains or is exhausted. In this case, the remaining second raw material gas R is exhausted.

In an alternative exemplary embodiment, when the second raw material gas R is supplied to the substrate SUB, a plasma is generated through the second plasma generating unit 122 of the second module MD2. In an exemplary embodiment, energy is selectively supplied from the generator GE (refers to FIG. 1) only to the second matcher MT2 through the switch SW, proper power is transmitted from the second matcher MT2 to the second plasma generating unit 122 through the second conductor unit 132, and the plasma is generated from the second plasma generating unit 122. The generated plasma may convert the second raw material gas R into a radical type, which may effectively react with a layer including the first raw material gas S.

Then, referring to FIG. 4E, the second raw material R is supplied from the third module MD3 adjacent to the second module MD2 to the substrate SUB, the purge gas P is supplied from the second module MD2 to the substrate SUB, and the first raw material gas S is supplied from the first module MD1 to the substrate SUB.

The purge gas P is supplied from the second nozzle unit 112 of the second module MD2 to the substrate SUB.

The second raw material valve VR and the third valve V3b among valves shown in FIG. 3 are open to supply the second raw material gas R from the third nozzle unit 113 to the substrate SUB.

In this case, the purge gas P is supplied from the second nozzle unit 112 of the second module MD2 to the substrate, removes extra layers and impurities remaining on the surface of the AlxOy layer disposed on a region of the surface of the substrate SUB facing the second module MD2, and provides a deposition layer including AlxOy on a region of the surface of the substrate SUB facing the second module MD2, so the deposition layer formation of one cycle on a region of the surface of the substrate SUB facing the first module MD2 is completed.

When the second raw material gas R is supplied from the third nozzle unit 113 of the third module MD3 to the substrate SUB, the gas reacts with the chemical adsorbing layer including the first raw material gas S already adsorbed on one of the regions of the substrate SUB facing the third module MD3 or substitutes a portion of the chemical adsorbing layer, and a desired deposition layer such as a AlxOy layer is ultimately provided. In this case, an extra second raw material gas R provides a physical adsorbing layer, and remains or is exhausted. In this case, the remaining second raw material gas R is exhausted.

In an alternative exemplary embodiment, when the second raw material gas R is supplied to the substrate SUB, a plasma is generated through the third plasma generating unit 123 of the third module MD3. In an exemplary embodiment, energy is selectively supplied from the generator GE (refers to FIG. 1) only to the third matcher MT3 through the switch SW, proper power is transmitted from the third matcher MT3 to the third plasma generating unit 123 through the third conductor unit 133, and a plasma is generated from the third plasma generating unit 123. The generated plasma may convert the second raw material gas R into a radical type, which may effectively react with a layer including the first raw material gas S.

The first raw material valve VS and the first valve V1c among valves shown in FIG. 3 are open to supply the first raw material gas S from the first nozzle unit 111 to the substrate SUB.

When the first raw material gas S is supplied to the substrate SUB, an adsorbing layer including aluminum (Al) is disposed on a surface of the substrate SUB including a region facing the first module MD1. In an exemplary embodiment, a chemical adsorbing layer and a physical adsorbing layer are disposed on a surface facing the first module MD1 of the substrate SUB. That is, an adsorbing layer including Al for providing a second AlxOy layer is disposed on a first AlxOy layer provided by the first cycle.

Then, referring to FIG. 4F, the first raw material S is supplied from the second module MD2 adjacent to the first module MD1 to the substrate, and the purge gas P is supplied from the first module MD1 and the third module MD3 to the substrate SUB.

The first raw material S is supplied from the second nozzle unit 112 of the second module MD2 to the substrate, and the purge gas P is supplied from the first nozzle unit 111 of the first module MD1 and the third nozzle unit 113 of the third module MD3 to the substrate SUB.

The first raw material valve VS and the second valve V2c among valves shown in FIG. 3 are open to supply the first raw material gas S from the second nozzle unit 112 to the substrate SUB.

The purge gas P is supplied from the third nozzle unit 113 of the third module MD3 to the substrate, removes extra layers and impurities remaining on the surface of the AlxOy layer disposed on a region of a surface of the substrate SUB facing the third module MD3, and provides a deposition layer including AlxOy on a region of a surface of the substrate SUB facing the third module MD3, so the deposition layer formation of one cycle on a region of the surface of the substrate SUB facing the first module MD3 is completed.

In this case, since the purge gas P is supplied from the first nozzle unit 111 of the first module MD1 to the substrate SUB, the physical adsorbing layer having weak intermolecular bond among the adsorbing layers disposed on a region of a surface of the substrate SUB facing the first module MD1 by using the first raw material gas S is separated and exhausted from the substrate SUB by the purge gas P.

When the first raw material gas S is supplied from the second nozzle unit 112 to the substrate SUB, an adsorbing layer including aluminum (Al) is disposed on a surface of the substrate SUB including a region facing the second module MD2. In an exemplary embodiment, a chemical adsorbing layer and a physical adsorbing layer are disposed on a surface of the substrate SUB facing the second module MD2. That is, an adsorbing layer including Al for providing a second AlxOy layer is disposed on a first AlxOy layer provided by the first cycle.

At least one AlxOy layer is disposed on all the regions of the substrate SUB through the processes shown in FIGS. 4A to 4F. Moreover, when such processes are repeated, desired AlxOy layers may be disposed on all the regions of the substrate SUB. That is, it is possible to ultimately provide AlxOy layers having the same thickness as a whole on the substrate SUB. However, the exemplary embodiment is not limited thereto and may also provide AlxOy layers having different thicknesses on all the regions of the substrate SUB.

When using the vapor deposition apparatus 100 according to the exemplary embodiment, it is possible to provide a uniform deposition layer on all the regions of the substrate SUB.

That is, since the plurality of modules MD1 to MD3 are arranged to face all the regions of the substrate SUB and deposition processes are performed on all the regions of the substrate SUB together, the efficiency and uniformity of deposition are enhanced. Thus, since there is no need to perform deposition processes while moving the substrate SUB and the vapor deposition apparatus 100, easiness in the layout of facilities and a space utilization capability are enhanced.

Moreover, since the plurality of modules MD1 to MD3 face all the regions of the substrate SUB, each of the plurality of modules MD1 to MD3 needs to face only portions of the substrate SUB, respectively. In addition, by independently supplying a plurality of raw material gases and a purge gas to the substrate SUB by the plurality of modules MD1 to MD3, the deposition layer formation process of the first cycle is independently performed on each region of the substrate SUB instead of performing the deposition layer formation process of the first cycle on all the regions of the substrate SUB together, That is, in the deposition processes, the thickness or the number of AlxOy layers may be different for each region of the substrate SUB facing the first module MD1, the second module MD2, and the third module MD3.

Through such an independent and distinct process, it is possible to minimize a process time needed for replacing each gas. Moreover, a time to perform the deposition layer formation process of one cycle decreases. Thus, the efficiency of a deposition process of disposing a deposition layer on the substrate SUB increases.

That is, the vapor deposition apparatus 100 and the vapor deposition method using the apparatus according to the exemplary embodiment may provide a thin layer by using atomic layer deposition (“ALD”), and it is possible to enhance the efficiency of an ALD process by reducing a time to perform the process of one cycle for providing one layer when performing the ALD process. The exemplary embodiment may also apply to other vapor deposition apparatuses in addition to an ALD apparatus.

In the exemplary embodiment, the types of the first raw material gas S and the second raw material gas R, and thin layers (e.g., AlxOy thin layer) provided by using such gases are exemplary, so it is possible to use various types of the first raw material gas S and the second raw material gas R and thus it is also possible to provide various thin layers.

Moreover, since the first raw material gas S is supplied from one module unit and a purge gas P is supplied from a module unit adjacent thereto, an adsorbing layer including the first raw material S is efficiently disposed on a region of the substrate SUB supplying the first raw material gas S and the mixing of impurities is easily inhibited by supplying the purge gas P to a region adjacent thereto.

Likewise, since the second raw material gas R is supplied from one module unit and a purge gas P is supplied from a module unit adjacent thereto, an adsorbing layer including the second raw material R is efficiently disposed on a region of the substrate SUB supplying the second raw material gas R and the mixing of impurities is easily inhibited by supplying the purge gas P to a region adjacent thereto.

Moreover, since the first raw material gas S is supplied in the order of the first module MD1, the second module MD2, and the third module MD3, deposition processes are sequentially performed on a region of the substrate SUB and a region adjacent thereto in one direction and thus it is possible to provide a uniform and purity-enhanced deposition layer on all the regions of the substrate SUB.

Moreover, since the second raw material gas R is supplied in the order of the first module MD1, the second module MD2, and the third module MD3, deposition processes are sequentially performed on a region of the substrate SUB and a region adjacent thereto in one direction and thus it is possible to provide a uniform and purity-enhanced deposition layer on all the regions of the substrate SUB.

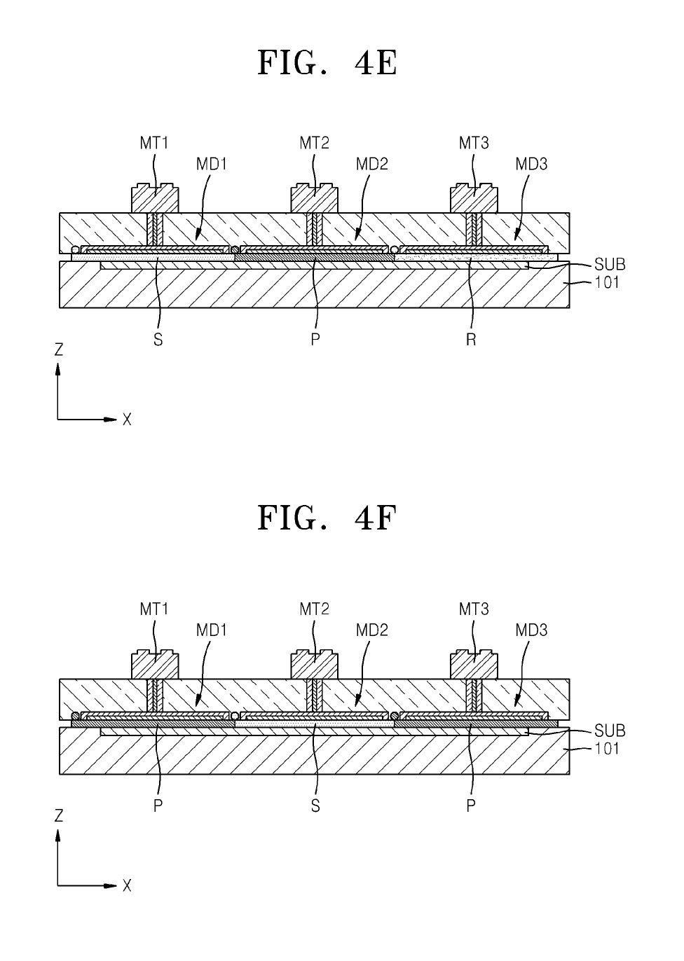

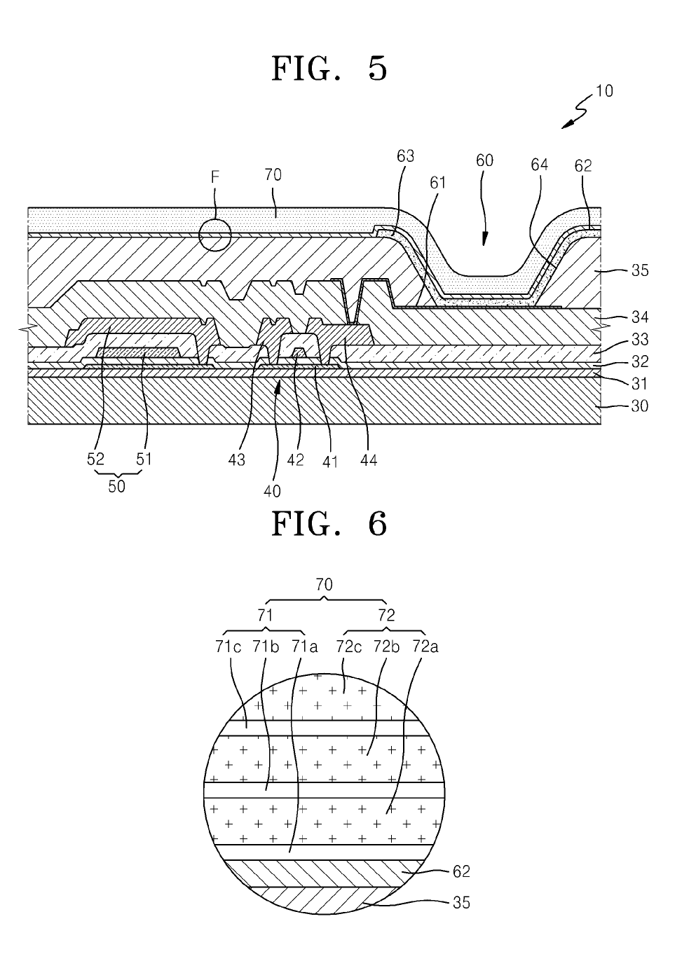

FIG. 5 is a schematic diagram of an organic light-emitting display (“OLED”) apparatus provided by using the method shown in FIGS. 4A to 4F, and FIG. 6 is an enlarged view of a circled part F of FIG. 5.

An OLED apparatus 10 is disposed on a substrate 30. In an exemplary embodiment, the substrate 30 may include a glass material, a plastic material, or a metal material.

A buffer layer 31 including an insulating material is arranged on the substrate 30 to provide planar surface on the top of the substrate 30 and to prevent moisture and foreign materials from permeating the substrate 30.

A thin film transistor (“TFT”) 40, a capacitor 50, and an organic light-emitting device 60 are disposed on the buffer layer 31. The TFT 40 includes an active layer 41, a gate electrode 42, a source electrode 43, and a drain electrode 44. The organic light-emitting device 60 includes a first electrode 61, a second electrode 62, and an intermediate layer 63.

The capacitor 50 includes a first capacitor electrode 51 and a second capacitor electrode 52.

In an exemplary embodiment, the active layer 41 provided in a certain pattern is arranged on the buffer layer 31. The active layer 41 may include an inorganic semiconductor material, an organic semiconductor material or an oxide semiconductor material.

A gate insulating layer 32 is disposed on the active layer 41. The gate electrode is disposed on the gate insulating layer 32 to face the active layer 41. An interlayer insulating layer 33 is provided to cover the gate electrode 42, and the source electrode 43 and the drain electrode 44 are disposed on the interlayer insulating layer 33 to be in contact with a region of the active layer 41.

The first capacitor electrode 51 is disposed in the same layer as the gate electrode 42 and may include the same material as that of the gate electrode 42.

The second capacitor electrode 52 is disposed in the same layer as the source electrode 43 and the drain electrode 44 and may include the same material as those of the source electrode 43 and the drain electrode 44.

A passivation layer 34 is provided to cover the source electrode 43 and the drain electrode 44 and a separate insulating layer may be further disposed on the passivation layer 34 for the planarization of the TFT 40.

The first electrode 61 is disposed on the passivation layer 34. The first electrode 61 is provided to be electrically connected to any one of the source electrode 43 and the drain electrode 44. In addition, a pixel defining layer 35 is provided to cover the first electrode 61. A certain opening 64 is defined in the pixel defining layer 35 and then the intermediate layer 63 including an organic emission layer is provided in a region defined by the opening 64. The second electrode 62 is disposed on the intermediate layer 63.

An encapsulating layer 70 is disposed on the second electrode 62. The encapsulating layer 70 may include an organic material or an inorganic material or have a structure in which the organic material and the inorganic material are alternately stacked.

The encapsulating layer 70 may be provided by using the above-described vapor deposition apparatus 100 of the invention. That is, a substrate 30 on which the second electrode 62 is disposed is arranged on the above-described vapor deposition apparatus 100 of the invention and then a desired layer may be provided. In an exemplary embodiment, the desired layer may be provided by using the method shown in FIGS. 4A to 4F.

In an exemplary embodiment, the encapsulating layer 70 may include one or more inorganic layers 71. In this case, when providing the one or more inorganic layers 71, it is possible to use the above-described vapor deposition apparatus 100.

In an alternative exemplary embodiment, referring to FIG. 6, the encapsulating layer 70 may include the inorganic layer 71 and an organic layer 72, the inorganic layer may include a plurality of layers 71a to 71c, and the organic layer may include a plurality of layers 72a to 72c. In this case, it is possible to use the plurality of layers 71a to 71c of the inorganic layer 71 by using the vapor deposition apparatus 100 of the invention.

However, the exemplary embodiment is not limited thereto. That is, the insulating layers of the OLED apparatus 10 including the buffer layer 31, the gate insulating layer 32, the interlayer insulating layer 33, the passivation layer 34, and the pixel defining layer 35 may be provided by using the vapor deposition apparatus of the invention.

Moreover, various thin layers including the active layer 41, the gate electrode 42, the source electrode 43, the drain electrode 44, the first electrode 61, the intermediate layer 63, and the second electrode 62 may also be provided by using the vapor deposition apparatus of the invention.

As described above, when using the vapor deposition apparatus of the invention, it is possible to enhance the characteristics of a deposition layer disposed on the OLED apparatus 10 and, as a result, the electrical characteristics and picture quality characteristics of the OLED apparatus 10.

According to the vapor deposition apparatus, the vapor deposition method and the method for manufacturing the OLED apparatus according to one or more exemplary embodiments of the invention, it is possible to easily enhance process efficiency and thin-layer characteristics.

As such, although the invention is described with reference to exemplary embodiments shown in the drawings, they are only examples and a person skilled in the art will understand that various variations may be made therefrom. Thus, the true protective scope of the invention will be defined by the technical spirit of the following claims.

What is claimed is:

1. A vapor deposition apparatus for depositing a thin layer on a substrate, the vapor deposition apparatus comprising:
a plurality of modules arranged to respectively face different regions of the substrate, each of the plurality of modules comprising:
a body unit; and
a nozzle unit disposed on one of surfaces of the body unit facing the substrate,
wherein the plurality of modules is configured to individually perform deposition processes on different regions of the substrate, respectively.

2. The vapor deposition apparatus of claim 1, wherein the nozzle units of the plurality of modules are configured to independently supply a plurality of types of gases selectively to the substrate.

3. The vapor deposition apparatus of claim 1, wherein the nozzle unit has a length corresponding to a width of the substrate taken along one direction.

4. The vapor deposition apparatus of claim 1, wherein each of the plurality of modules further comprises a plasma generating unit which is disposed on the one of the surfaces of the body unit facing the substrate and spaced apart from the nozzle unit.

5. The vapor deposition apparatus of claim 4, further comprising:
a plurality of matchers corresponding respectively to the plasma generating units of the plurality of modules; and
a generator commonly connected to the plurality of matchers.

6. The vapor deposition apparatus of claim 5, further comprising a switch arranged between the generator and the plurality of matchers and configured to transmit energy generated from the generator to a selected one of the plurality of matchers.

7. The vapor deposition apparatus of claim 1, wherein the plurality of modules has a size equal to or greater than an entire region of the substrate.

8. A vapor deposition method for providing a thin layer on a substrate, the vapor deposition method comprising:
providing a vapor deposition apparatus which comprises a plurality of modules arranged to respectively face different regions of the substrate, each of the plurality of modules comprising:
a body unit; and
a nozzle unit which is disposed on one of surfaces of the body unit facing the substrate;
arranging the substrate to face the plurality of modules of the vapor deposition apparatus;
sequentially supplying a plurality of raw material gases independently by the plurality of modules to the different regions of the substrate, and
providing the thin layer on the substrate.

9. The vapor deposition method of claim 8, further comprising selectively supplying a first raw material gas, a second raw material gas, and a purge gas to the substrate independently by the nozzle units of the plurality of modules.

10. The vapor deposition method of claim 9, further comprising supplying the first raw material gas or the second raw material gas by one of the nozzle units of the plurality of modules while supplying the purge gas to the substrate by another nozzle unit adjacent to the one of the nozzle units.

11. The vapor deposition method of claim 9, wherein the nozzle units of the plurality of modules are arranged in one direction, and
the method further comprises supplying the first raw material gas or the second raw material gas to the substrate by the plurality of modules in an arranged order.

12. The vapor deposition method of claim 8, wherein each of the plurality of modules further comprises a plasma generating unit which is disposed on the one of the surfaces of the body unit facing the substrate and spaced apart from the nozzle unit, and
the method further comprises generating a plasma by the plasma generating unit while supplying at least one raw material gas in the providing the thin layer.

13. The vapor deposition method of claim 12, wherein the plasma generating units of the plurality of modules independently generate plasmas.

14. The vapor deposition method of claim 8, wherein the providing the thin layer on the substrate is performed while the substrate is fixed to the vapor deposition apparatus.

15. A method of manufacturing an organic light-emitting display apparatus comprising one or more thin layers on a substrate, the method comprising:
providing a vapor deposition apparatus which comprises a plurality of modules arranged to respectively face different regions of the substrate, each of the plurality of modules comprising:
a body unit; and
a nozzle unit which is disposed on one of surfaces of the body unit facing the substrate;
arranging the substrate to face the plurality of modules of the vapor deposition apparatus;
sequentially supplying a plurality of raw material gases independently by the plurality of modules to the different regions of the substrate, and.
providing a thin layer on the substrate.

16. The method of claim 15, wherein the providing the thin layer on the substrate comprises selectively supplying a first raw material gas, a second raw material gas, and a purge gas to the substrate independently by the nozzle units of the plurality of modules.

17. The method of claim 16, further comprising supplying the first raw material gas or the second raw material gas by one of the nozzle units of the plurality of modules while supplying the purge gas to the substrate by another nozzle unit adjacent to the one of the nozzle units.

18. The method of claim 15, wherein each of the plurality of modules further comprises a plasma generating unit which is disposed on the one of the surfaces of the body unit facing the substrate and spaced apart from the nozzle unit, and
the sequentially supplying the plurality of raw material gases further comprises generating a plasma by the plasma generating unit while supplying at least one raw material gas.

19. The method of claim 15, wherein the organic light-emitting display apparatus comprises:
an organic light-emitting device which comprises:
a first electrode;
a second electrode; and
an intermediate layer which is arranged between the first electrode and the second electrode and comprises an organic emission layer, and
the providing the thin layer on the substrate comprises providing an encapsulating layer which encapsulates the organic light-emitting device.

20. The method of claim 15, wherein the providing the thin layer on the substrate comprises providing one or more insulating layers or conductive layers which are comprised in the organic light-emitting display apparatus.
